(19) United States
(12) Patent Application Publication
(10) Pub. No.: US 2026/0156949 A1
(43) Pub. Date: Jun. 4, 2026

(54) ESD Protection Semiconductor Device

(71) Applicant: Joulwatt Technology Co., Ltd., Hangzhou City (CN)

(72) Inventor: Guangtao Han, Hangzhou City (CN)

(21) Appl. No.: 19/330,374

(22) Filed: Sep. 16, 2025

(30) Foreign Application Priority Data
Dec. 4, 2024 (CN) 202411777826.9

(51) Int. Cl. H10D 89/60

(52) U.S. Cl. CPC H10D 89/814

(57) ABSTRACT

An electrostatic discharge (ESD) protection semiconductor device includes a well region in an upper portion of a substrate. A drain region and a source region are located respectively at two opposing ends in an upper portion of the well region. A gate layer is located over the well region, adjacent and electrically connected to the source region. A field plate layer is located over the well region, with a first end adjacent to and electrically connected to the drain region, and a gap between a second end of the field plate layer and the gate layer. A first N+ doped region and a first P+ doped region are located in the well region below the gap and adjacent to each other. Second N+ doped region(s) and second P+ doped region(s) are alternately arranged in the field plate layer. At least one PN junction is formed in the field plate layer.

### CROSS-REFERENCE TO RELATED APPLICATIONS

This patent application claims priority to China Patent Application No. 202411777826.9, filed on Dec. 4, 2024 and entitled “ESD PROTECTION SEMICONDUCTOR DEVICE,” which is hereby incorporated by reference herein as if reproduced in its entirety.

### TECHNICAL FIELD

The present disclosure relates generally to the field of semiconductor technology, and in particular embodiments, to techniques and mechanisms of semiconductor devices and integrated circuits for Electrostatic discharge (ESD) protection.

### BACKGROUND

Electrostatic discharge (ESD) is a natural phenomenon that exists throughout the product lifecycle. While not easily perceived by the human body, ESD can pose a serious threat to integrated circuit products. During manufacturing, packaging, testing and application of chips, a certain amount of charge is accumulated in the external environment and internal structures of the chips, exposing them to the threat of static electricity. Therefore, chip design requires the placement of ESD protection devices at pins. A gate-grounded NMOS (GGNMOS) structure is often used as an ESD protection device.

FIG. 1 shows a schematic cross-sectional view of a conventional GGNMOS ESD protection semiconductor device. As shown in FIG. 1, the semiconductor device includes a substrate 10 and a well region 20 located at the top portion of the substrate 10. It also includes a drain region and a source region located at two ends of the top of the well region 20. The drain region is an N+ doped region 31, the source region is an N+ doped region 32, and a body region is in contact with the source region. The body region is a P+ doped region 33, and both the substrate 10 and the well region 20 are P-type doped. The semiconductor device also includes a gate layer 41, e.g., a field plate layer made of polycrystalline silicon, located between the drain region and the source region. The drain region is connected to a pin of device to be protected, i.e., an I/O port. The source region, the gate region and the body region may all be grounded or connected to a GND pin.

When the drain region receives a large electrostatic pulse, avalanche breakdown occurs first between the drain region (the N+ doped region 31) and the well region 20 (the P-type well region), generating a current within the well region 20 and a voltage drop across the resistor within the well region 20. This turns on an NPN transistor that is from the N+ doped region 31 to the well region 20 and then to the N+ doped region 32, forming a current discharge path from the drain to the source. The value of the breakdown voltage (BV) of this semiconductor device depends on the breakdown voltage of the junction formed between the N+ doped region 31 and the P-type well region 20, and is substantially the same as that of a conventional NMOS device. A higher breakdown voltage requires a higher trigger voltage, resulting in poor protection effect. Therefore, the current ESD protection devices in the GGNMOS structure have poor ESD protection capabilities.

### SUMMARY

In view of the above problems, an objective of the present disclosure is to provide an ESD protection semiconductor device to solve the problems in the prior art. Technical advantages are generally achieved, by embodiments of this disclosure which describe an electrostatic discharge (ESD) protection semiconductor device.

According to one aspect of the present disclosure, there is provided an ESD protection semiconductor device, comprising: a well region located in an upper portion of a substrate; a drain region and a source region, respectively located at opposite first and second ends in an upper portion of the well region, the source region being grounded, and the drain region being connected to a device pin; a gate layer, located over the well region, adjacent to and electrically connected to the source region; a field plate layer, located over the well region, a first end of the field plate layer being adjacent to and electrically connected to the drain region, and a gap being provided between a second end of the field plate layer and the gate layer; adjacent first N+ doped region and first P+ doped region, located in the well region below the gap; and second N+ doped region(s) and second P+ doped region(s), located in the field plate layer and alternately arranged, wherein the second N+ doped region(s) and second P+ doped region(s) in the field plate layer form at least one forward PN junction and/or at least one reverse PN junction.

Optionally, a first end and a second end of the field plate layer are provided with the second N+ doped region(s), and a second N+ doped region at the first end of the field plate layer is electrically connected to the drain region, and a second N+ doped region at the second end of the field plate layer is electrically connected to the first N+ doped region in the well region.

Optionally, the ESD protection semiconductor device also includes: a conductive layer, covering a portion of the first N+ doped region and the first end and the second end of the field plate layer, wherein the first N+ doped region not covered by the conductive layer and the first P+ doped region form a PN junction, and a second N+ doped region not covered by the conductive layer and a second P+ doped region form a PN junction.

Optionally, when the ESD protection semiconductor device is in operation, the drain region receives an electrostatic pulse, causing the PN junction in the field plate layer to be turned on, and a reverse PN junction formed by the first N+ doped region and the first P+ doped region to be broken down, and a current flows from the well region to the source region, such that a transistor composed of the drain region, the well region and the source region is turned on to form a current discharge path.

Optionally, from the first end to the second end of the field plate layer, adjacent second P+ doped region and second N+ doped region not covered by the conductive layer form a forward PN junction, and adjacent second N+ doped region and second P+ doped region not covered by the conductive layer form a reverse PN junction.

Optionally, when a plurality of PN junctions are formed in the field plate layer, the a plurality of PN junctions are connected in series.

Optionally, the first P+ doped region partially surrounds the first N+ doped region, and the conductive layer exposes an entire surface of the first P+ doped region and exposes a portion of a surface of the first N+ doped region adjacent to the first P+ doped region.

Optionally, the first N+ doped region is adjacent to the gate layer, and the first P+ doped region is located between the first N+ doped region and the field plate layer, or the first N+ doped region is adjacent to the field plate layer, and the first P+ doped region is located between the first N+ doped region and the gate layer.

Optionally, a second P+ doped region is formed between the second N+ doped region at the first end of the field plate layer and the second N+ doped region at the second end of the field plate layer. When the conductive layer completely exposes the second P+ doped region and partially exposes the second N+ doped region at the first end of the field plate layer and the second N+ doped region at the second end of the field plate layer, adjacent reverse PN junction and forward PN junction are formed in the field plate layer; when the conductive layer only exposes a portion of the second N+ doped region at the second end of the field plate layer and a portion of the second P+ doped region, a forward PN junction is formed in the field plate layer; when the conductive layer only exposes a portion of the second N+ doped region at the first end of the field plate layer and a portion of the second P+ doped region, a reverse PN junction is formed in the field plate layer.

Optionally, a plurality of second P+ doped regions are formed between the second N+ doped region at the first end of the field plate layer and the second N+ doped region at the second end of the field plate layer, the conductive layer only covers a portion of the second N+ doped region at the first end of the field plate layer and a portion of the second N+ doped region at the second end of the field plate layer, and reverse PN junction(s) and forward PN junction(s) are alternately distributed in the field plate layer.

Optionally, the conductive layer is metal silicide, and the field plate layer is a polysilicon layer.

According to another aspect of the present disclosure, an ESD protection semiconductor device is provided that includes: a well region located in an upper portion of a substrate; a drain region and a source region, located respectively at a first end and a second end opposite to each other in an upper portion of the well region, the source region being grounded, and the drain region being connected to a device pin; a gate layer, located over the well region, adjacent to and electrically connected to the source region; a field plate layer, located over the well region, wherein a first end of the field plate layer is adjacent to and electrically connected to the drain region, and a gap is provided between a second end of the field plate layer and the gate layer; a first N+ doped region and a first P+ doped region, located in the well region below the gap and adjacent to each other; and one or more second N+ doped regions and one or more second P+ doped regions, located in the field plate layer and alternately arranged; wherein at least one forward PN junction and/or at least one reverse PN junction is/are formed in the field plate layer.

According to yet another aspect of the present disclosure, an ESD protection semiconductor device is provided that includes: a well region in a substrate, extending from a top surface of the substrate into the substrate; a drain region and a source region in the well region, extending from a top surface of the well region into the well region, wherein the drain region is located at a first end of the well region, the source region is located at a second end of the well region opposite to the first end of the well region, and the drain region is connected to a device to be protected for electrostatic discharge (ESD); a gate layer and a field plate layer, disposed on the top surface of the well region between the first end and the second end of the well region and spaced apart, wherein the gate layer is adjacent to the source region, and the field plate layer is adjacent to the drain region; a first N+ doped region and a first P+ doped region, located in the well region between the gate layer and the field plate layer, and adjacent to each other; a conductive layer covering the source region, the drain region, the gate layer, a portion of the field plate layer, and a portion of the first N+ doped region; and one or more N+ doped regions and one or more P+ doped regions alternately arranged in the field plate layer, wherein at least one PN junction is formed by the one or more N+ doped regions and the one or more P+ doped regions in the field plate layer.

According to yet another aspect of the present disclosure, an ESD protection semiconductor device is provided that includes: a substrate; a well region in the substrate, extending from a top surface of the substrate into the substrate; a drain region and a source region in the well region, extending from a top surface of the well region into the well region, wherein the drain region is located at a first end of the well region, the source region is located at a second end of the well region opposite to the first end of the well region, the source region is grounded, and the drain region is connected to a device to be protected for electrostatic discharge (ESD); a gate layer and a field plate layer on the top surface of the well region between the first end and the second end of the well region, wherein the gate layer and the field plate layer are spaced apart with a gap in between, the gate layer is adjacent to and electrically connected to the source region, and the field plate layer is adjacent to the drain region; a first N+ doped region and a first P+ doped region, located in the well region below the gap, and adjacent to each other; a conductive layer covering the source region, the drain region, the gate layer, a portion of the field plate layer, and a portion of the first N+ doped region; and one or more N+ doped regions and one or more P+ doped regions alternately arranged in the field plate layer, wherein the one or more N+ doped regions and the one or more P+ doped regions comprise: a second N+ doped region disposed at a first end of the field plate layer, the first end of the field plate layer adjacent to and electrically connected to the drain region; a third N+ doped region disposed at a second end of the field plate layer opposite to the first end of the field plate layer, the second end of the field plate layer electrically connected to the first N+ doped region; and at least one second P+ doped region disposed between the second N+ doped region and the third second N+ doped region; wherein at least one PN junction is formed by the one or more N+ doped regions and the one or more P+ doped regions in the field plate layer, the at least one PN junction including a forward PN junction or a reverse PN junction.

According to yet another aspect of the present disclosure, there is provided an integrated circuit comprising the above-mentioned ESD protection semiconductor device.

In the ESD protection semiconductor devices provided by the present disclosure, based on the GGNMOS structure, adjacent first N+ doped regions and first P+ doped regions are formed in the well region, such that the breakdown junction is transferred from the N+ doped region to the P-type well region to the first N+ doped region to the first P+ doped region. Since the concentration of the first P+ doped region is high, the breakdown voltage during breakdown is low, and thus the breakdown voltage of the ESD protection semiconductor device can be reduced, and the ESD protection capability of the ESD protection semiconductor device is improved. In order to simultaneously ensure the voltage withstand capability of the ESD protection semiconductor device, a field plate layer separated from the gate layer is also provided over the well region, and the second N+ doped region(s) and the second P+ doped region(s) are arranged in the field plate layer to form a forward or reverse PN junction(s) in the field plate layer. This improves the voltage withstand capability of the device while reducing the breakdown voltage, and avoids false triggering while improving the ESD protection capability.

Further, the conductive layer is disposed on the field plate layer, exposing portions of the surfaces of the second N+ doped region(s) and the second P+ doped region(s). The second N+ doped region(s) and the second P+ doped region(s) not covered by the conductive layer form PN(s) junction. This allows the direction and number of the PN junctions within the field plate layer to be adjusted by adjusting the position of the conductive layer and the number of doped regions covered by the conductive layer, thereby achieving the objective of freely adjusting the device's withstand voltage. This enables flexible adjustment of the breakdown voltage and withstand voltage of the semiconductor device, and enhances electrostatic protection capabilities. Aspects of the present disclosure may be applied for protection of devices with various operating voltages, broadening application scenarios and enhancing applicability.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

The above described and other objectives, features and advantages of the present disclosure will become clearer through the following description of embodiments of the present disclosure with reference to the accompanying drawings, in which:

FIG. 1 is a schematic cross-sectional structure diagram of an existing GGNMOS electrostatic discharge (ESD) protection semiconductor device;

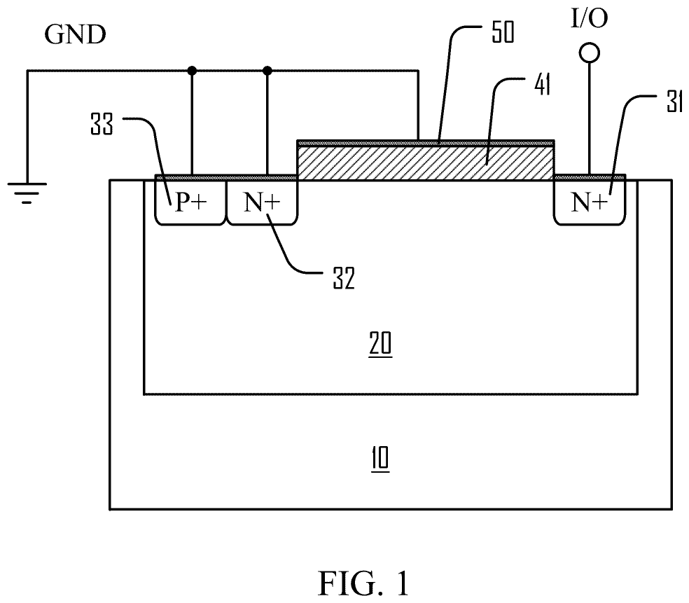

FIG. 2 is a schematic cross-sectional view of a semiconductor device for ESD protection according to a first embodiment of the present disclosure;

FIG. 3 is a schematic cross-sectional view of a semiconductor device for ESD protection according to a second embodiment of the present disclosure;

FIG. 4 is a schematic cross-sectional view of a semiconductor device for ESD protection according to a third embodiment of the present disclosure;

FIG. 5 is a schematic cross-sectional view of a semiconductor device for ESD protection according to a fourth embodiment of the present disclosure; and

FIG. 6 is a schematic cross-sectional view of a semiconductor device for ESD protection according to a fifth embodiment of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Furthermore, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to embodiments in a specific context, namely ESD protection semiconductor devices. The disclosure may also be applied, however, to a variety of apparatuses that require ESD protection.

Various embodiments of the present disclosure will be described in more detail below with reference to the accompanying drawings. In various figures, identical elements are denoted by identical or similar reference symbols or numerals. For clarity, parts in the figures may not be drawn to scale. Furthermore, certain commonly known parts may not be shown. For simplicity, a single figure may be used to depict a semiconductor structure obtained after several steps.

When describing the structure of a device, when a layer or region is referred to as being “on” or “over” another layer or region, it may mean that the layer or region is directly on another layer or region, or that other layers or regions are included between the layer or region and another layer or region. Furthermore, if the device is turned over, the layer or region will be “below” or “beneath” another layer or region. In this application, the term “semiconductor structure” is a general term referring to an entire semiconductor structure formed in various steps of semiconductor device manufacturing, including all layers or regions that have been formed.

Unless otherwise specified below, various layers or regions of a semiconductor device may be formed of materials known to those skilled in the art. Examples of semiconductor materials include III-V semiconductors, such as GaAs, InP, GaN and SiC, and IV semiconductors, such as Si and Ge. Gate conductors and electrode layers may be formed of various conductive materials, such as metal layers, doped polysilicon layer, or stacked gate conductors comprising a metal layer and a doped polysilicon layer, or other conductive materials, such as TaC, TiN, TaSiN, HfSiN, TiSiN, TiCN, TaAlC, TiAlN, TaN, PtSix, Ni3Si, Pt, Ru, W, and a combination thereof.

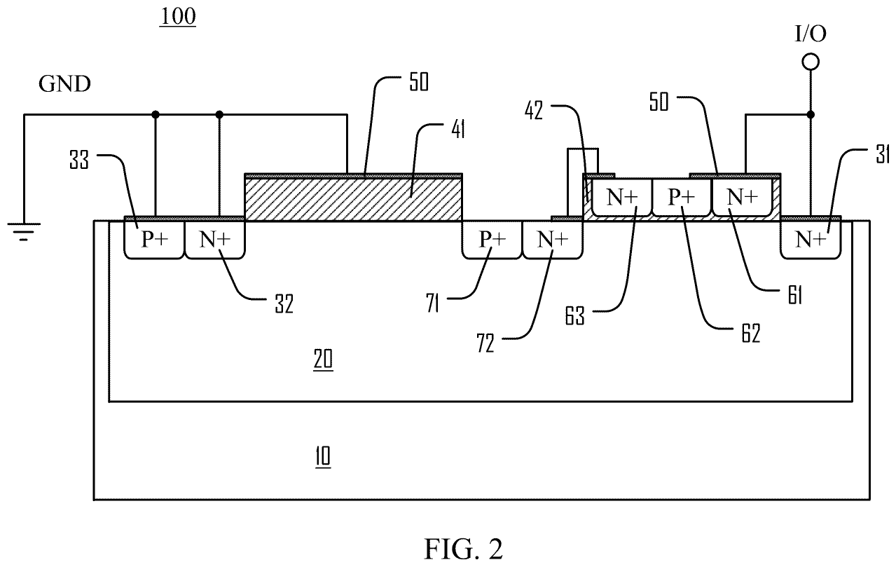

FIG. 2 is a schematic cross-sectional view of an ESD protection semiconductor device 100 according to a first embodiment of the present disclosure.

As shown in FIG. 2, the ESD protection semiconductor device 100 of this embodiment includes a substrate 10, a well region 20 located in the upper portion of the substrate 10, and a drain region and a source region located in the upper portion of the well region 20. Both the substrate 10 and the well region 20 are, for example, P-type doped. The well region 20 may extend from a top surface of the substrate 10 toward a bottom of the substrate 10 and into the substrate 10. The drain region and the source region are located respectively at a first end and a second end of the upper portion of the well region 20, where the first end and the second end are opposite to each other. The source region is connected to a ground (GND) and the drain region is connected to a device pin (an I/O port). The drain region includes at least an N+ doped region 31, and the source region includes at least an N+ doped region 32. Within the well region 20, there is also a P+ doped region 33 adjacent to the N+ doped region 32, serving as the body region. A gate layer 41, such as a polysilicon layer, is located over the well region 20 between the source region and the drain region. The gate layer 41, the source region, and the body region are all connected to a reference ground via connecting wires. In this embodiment, a field plate layer 42 is disposed over the well region 20 and is separated from the gate layer 41. A first end of the field plate layer 42 is adjacent to and electrically connected to the drain region, and a gap is provided between a second end of the field plate layer 42 and the gate layer 41. The field plate layer 42 may, for example, also be a polysilicon layer, and may be formed in the same process step as the gate layer 41. A first N+ doped region 72 and a first P+ doped region 71, adjacent to each other, are disposed in the well region 20 below the gap between the gate layer 41 and the field plate layer 42. The first N+ doped region 72 is electrically connected to the second end of the field plate layer 42.

The ESD protection semiconductor device 100 further includes second N+ doped regions and second P+ doped regions are alternately arranged in the field plate layer 42. The second N+ doped regions and the second P+ doped regions in the field plate layer 42 form at least one forward PN junction and/or at least one reverse PN junction. Specifically, a second N+ doped region 61 is disposed at the first end of the field plate layer 42, and a second N+ doped region 63 is distributed at the second end of the field plate layer 42. The second N+ doped region 61 at the first end of the field plate layer is electrically connected to the drain region, and the second N+ doped region 63 at the second end of the field plate layer is electrically connected to the first N+ doped region 72 in the well region 20.

Furthermore, the ESD protection semiconductor device 100 includes a conductive layer 50. The conductive layer 50 covers the well region 20, the gate layer 41 and the field plate layer 42, and exposes at least a portion of the field plate layer 42 and a portion of the well region 20 below the gap (the gap between the gate layer 41 and the field plate layer 42 mentioned above). For example, the conductive layer 50 covers a portion of the first N+ doped region 72 and the first end and the second end of the field plate layer 42. The second N+ doped region and the second P+ doped region in the field plate layer 42 that are not covered by the conductive layer 50 form a PN junction. The first N+ doped region 72 and the first P+ doped region 71 in the well region 20 below the gap that are not covered by the conductive layer 50 form a PN junction.

When the ESD protection semiconductor device 100 is in operation and the drain region receives an electrostatic pulse, in a direction from the first end of the field plate layer 42 toward the second end of the field plate layer 42, a forward PN junction may be formed between adjacent second P+ doped region and second N+ doped region that are not covered by the conductive layer 50, and a reverse PN junction may be formed between adjacent second N+ doped region and second P+ doped region that are not covered by the conductive layer 50. The conductive layer 50 may be, for example, a metal silicide and may be interconnected via conductive wires. In the well region, the PN junction formed between the first N+ doped region 72 and the first P+ doped region 71 that are not covered by the conductive layer 50 undergoes reverse breakdown. As shown in FIG. 2, a second P+ doped region 62 is formed between the second N+ doped region 61 at the first end of the field plate layer 42 and the second N+ doped region 63 at the second end of the field plate layer 42. When the conductive layer 50 only exposes a portion of the second N+ doped region 63 and a portion of the second P+ doped region 62 at the second end of the field plate layer 42, a positive PN junction is formed in the field plate layer 42, namely, a positive PN junction is formed between the second P+ doped region 62 and the second N+ doped region 63. Therefore, when an electrostatic pulse is applied to the drain region, the electrostatic current first flows from the drain region to the second N+ doped region 61 and the second P+ doped region 62 through the conductive layer 50, then flows to the second N+ doped region 63 through the positive PN junction, and flows through the conductive layer 50 to the first N+ doped region 72.

In this embodiment, the first P+ doped region 71 partially surrounds the first N+ doped region 72, and the surface of the first P+ doped region 71 is not covered by the conductive layer 50. Furthermore, the conductive layer 50 may also expose a portion of the surface of the first N+ doped region 72 adjacent to the first P+ doped region 71. For example, the first N+ doped region 72 is adjacent to the field plate layer 42, the first P+ doped region 71 is located in the well region 20 between the gate layer 41 and the first N+ doped region 72, and the conductive layer 50 exposes the entire upper surface of the first P+ doped region 71 and a portion of the surface of the first N+ doped region 72 adjacent to the first P+ doped region 71. At this point, the PN junction between the first N+ doped region 72 and the first P+ doped region 71, which is not covered by the conductive layer 50, undergoes reverse breakdown, causing current to flow through the well region 20, and the current flows out of the source region through the well region 20. As a result, the NPN-type transistor structure formed by the N+ doped region 31 (the drain region), the well region 20, and the N+ doped region 32 (the source region) is turned on. This forms a current discharge path from the drain region to the source region. The drain region may be considered as an anode, and the source region may be considered as a cathode.

In other embodiments, the first N+ doped region 72 may be adjacent to the gate layer 41, the first P+ doped region 71 may be located in the well region 20 between the first N+ doped region 72 and the field plate layer 42, and the conductive layer 50 exposes the entire surface of the first P+ doped region 71 and a portion of the surface of the first N+ doped region 72 adjacent to the first P+ doped region 71. The current discharge path of the ESD protection semiconductor device during operation is the same as that described above and will not be repeated here.

In other embodiments, the first P+ doped region 71 and the first N+ doped region 72 may be located side by side between the gate layer 41 and the field plate layer 42. Taking the extension direction from the gate layer 41 to the field plate layer 42 as the device length direction, the device width direction is perpendicular to the length direction, and the first P+ doped region 71 and the first N+ doped region 72 may be arranged along the device width direction.

Thus, in this embodiment, the single-layer polysilicon structure of the GGNMOS is modified into a double-layer polysilicon structure by adding the field plate layer 42. The newly added field plate layer 42 includes the second N+ doped region(s) and the second P+ doped region(s). A forward or reverse PN junction may be formed at regions of a second N+ doped region and a second P+ doped region, where the regions are not covered by the conductive layer 50. When the ESD protection semiconductor device 100 is in operation, the drain region receives an electrostatic pulse, which causes the PN junction in the field plate layer 42 to conduct, and causes the PN junction formed by the first N+ doped region 72 and the first P+ doped region 71 to undergo reverse breakdown, resulting in current flowing in the well region 20. The current flows from the well region 20 to the source region, and causes the NPN transistor structure formed by the drain region, the well region 20 and the source region to conduct, thereby forming a current discharge path from the drain region to the source region. Because the first N+ doped region 72 and the first P+ doped region 71 are both highly doped regions, the breakdown voltage BV between them is very low, easily triggering the electrostatic protection. Further, the overall voltage withstand capability of the ESD protection semiconductor device 100 is improved by the PN junction in the newly added field plate layer 42, and thus the ESD protection semiconductor device may be applied in scenarios with higher operating voltages.

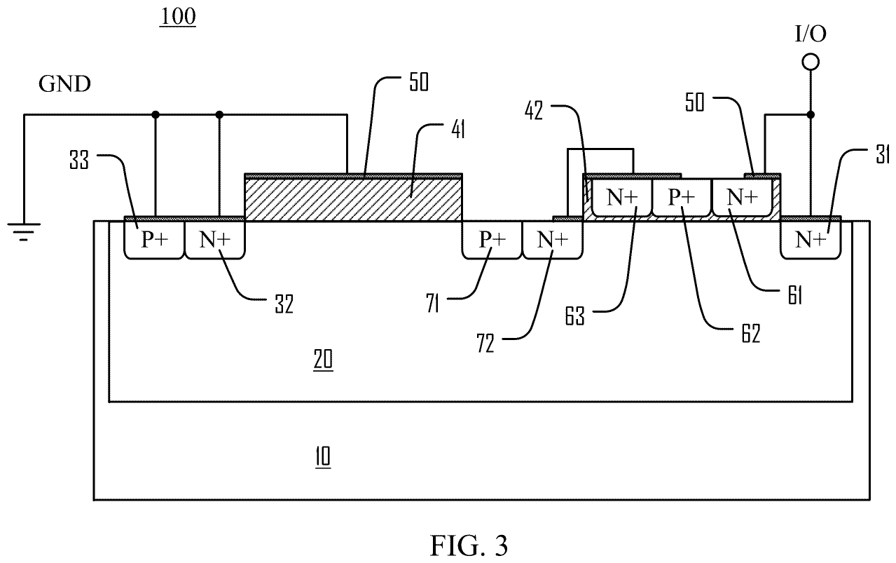

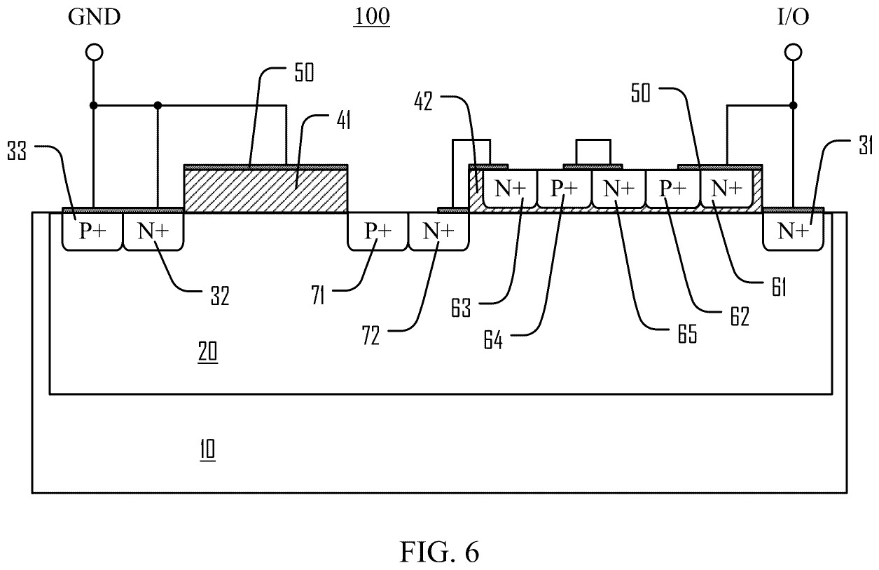

Furthermore, the number and direction of the PN junctions in the field plate layer 42 may be adjusted as needed in order to obtain a suitable value of the breakdown voltage BV. When multiple PN junctions are formed in the field plate layer 42, the multiple PN junctions are connected in series, and the PN junction in the well region 20 is then caused to reversely break down to generate current in the well region 20, which causes the NPN transistor structure formed by the drain region, the well region 20 and the source region to conduct, thereby forming a current discharge path from the anode to the cathode. The presence of the PN junctions in the field plate layer 42 and the well region 20 is for adjusting the trigger voltage of the ESD protection semiconductor device, such that the NPN transistor structure is turned on as needed to discharge current. In this embodiment, if multiple forward PN junctions connected in series are needed (to be described in FIG. 6), and in order to save device area and process costs, the multiple forward PN junctions connected in series may also be replaced with a small number of reverse PN junctions, such as the ESD protection semiconductor device in FIG. 3.

FIG. 3 is a schematic cross-sectional view of a ESD protection semiconductor device 100 according to a second embodiment of the present disclosure.

As shown in FIG. 3, the ESD protection semiconductor device 100 of this embodiment also includes a substrate 10, a well region 20, a drain region (N+ doped region 31), a source region (N+ doped region 32), a body region (P+ doped region 33), a gate layer 41, a field plate layer 42, a conductive layer 50, a first N+ doped region 72, a first P+ doped region 71, second N+ doped regions 61 and 63, and a second P+ doped region 62. The positional arrangement of these regions is the same as that of the embodiment shown in FIG. 2, except that, in this embodiment, the conductive layer 50 covers the second N+ doped region 63 and a portion of the second P+ doped region 62 at the second end of the field plate layer 42, and also covers a portion of the second N+ doped region 61 at the first end of the field plate layer 42. In this case, the second N+ doped region 61 and the second P+ doped region 62 in the field plate layer 42 that are not covered by the conductive layer 50 form an reverse PN junction. During operation, the ESD protection semiconductor device 100 receives an electrostatic pulse at the drain region, and a reverse PN junction is formed by the adjacent second P+ doped region 62 and the second N+ doped region 61 not covered by the conductive layer 50, from the first end to the second end of the field plate layer 42. Further, the PN junction between the first N+ doped region 72 and the first P+ doped region 71 undergoes reverse breakdown, causing current to flow through the well region 20. This turns on the NPN transistor structure composed of the drain region, the well region 20 and the source region, forming a current discharge path from the anode (the drain region) to the cathode (the source region). The current flowing through the well region 20 may be considered, to a certain extent, as a current controlling the conduction of the NPN transistor.

Similarly, the number of the reverse PN junctions in the field plate layer 42 may be adjusted as needed in order to obtain a value of a suitable breakdown voltage BV. When multiple reverse PN junctions are formed in the field plate layer 42, the multiple reverse PN junctions are connected in series.

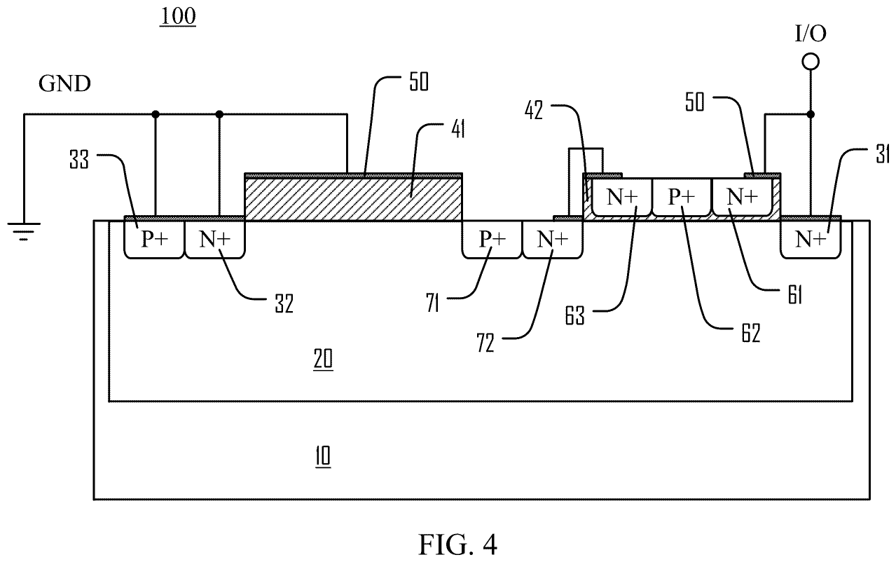

FIG. 4 is a schematic cross-sectional view of a ESD protection semiconductor device according to a third embodiment of the present disclosure.

As shown in FIG. 4, the ESD protection semiconductor device 100 of this embodiment also includes a substrate 10, a well region 20, a drain region (N+ doped region 31), a source region (N+ doped region 32), a body region (P+ doped region 33), a gate layer 41, a field plate layer 42, a conductive layer 50, a first N+ doped region 72, a first P+ doped region 71, second N+ doped regions 61 and 63, and a second P+ doped region 62. The positional arrangement of these regions is the same as that of the embodiment of FIG. 2, except that, in this embodiment, in the field plate layer 42, the conductive layer 50 completely exposes the second P+ doped region 62 and partially exposes the second N+ doped region 61 at the first end of the field plate layer 42 and the second N+ doped region 63 at the second end of the field plate layer 42, and adjacent reverse PN junction and forward PN junction are formed in the field plate layer 42. That is, when the ESD protection semiconductor device 100 is in operation, the drain region receives an electrostatic pulse, turning on a reverse PN junction and a forward PN junction in the field plate layer 42, and reversely breaking down the PN junction in the well region 20, and then the NPN transistor is turned on, forming a current discharge path from the drain region to the source region.

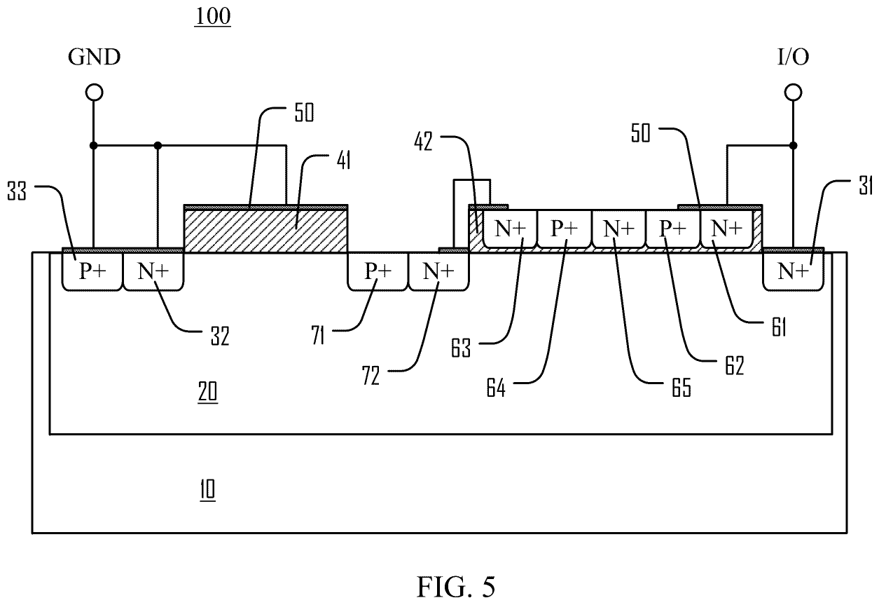

FIG. 5 is a schematic cross-sectional view of a ESD protection semiconductor device according to a fourth embodiment of the present disclosure.

As shown in FIG. 5, the ESD protection semiconductor device 100 of this embodiment also includes a substrate 10, a well region 20, a drain region (N+ doped region 31), a source region (N+ doped region 32), a body region (P+ doped region 33), a gate layer 41, a field plate layer 42, a conductive layer 50, a first N+ doped region 72, a first P+ doped region 71, second N+ doped regions 61 and 63, and a second P+ doped region 62. The positional arrangement of these regions is the same as that of the embodiment of FIG. 2, except that, in this embodiment, multiple second P+ doped regions are formed between the second N+ doped region 61 at the first end of the field plate layer 42 and the second N+ doped region 63 at the second end of the field plate layer 42. Specifically, from the first end to the second end of the field plate layer 42, the second N+ doped region 61, the second P+ doped region 62, a second N+ doped region 65, a second P+ doped region 64, and the second N+ doped region 63 are sequentially disposed. In this embodiment, in the field plate layer 42, when the conductive layer 50 covers the second N+ doped region 61 at the first end of the field plate layer 42 and a portion of the second P+ doped region 62 at the first end of the field plate layer 42, and covers a portion of the second N+ doped region 63 at the second end of the field plate layer 42, reverse PN junction(s) and forward PN junction(s) may be alternately arranged in the field plate layer. The conductive layer 50 exposes the second N+ doped region 65 and the second P+ doped region 64. Specifically, a forward PN junction is formed by the second P+ doped region 62 and second N+ doped region 65, a reverse PN junction is formed by the second N+ doped region 65 and the second P+ doped region 64, and a forward PN junction is formed by the second P+ doped region 64 and the second N+ doped region 63.

FIG. 6 is a schematic cross-sectional view of a ESD protection semiconductor device according to a fifth embodiment of the present disclosure.

As shown in FIG. 6, the ESD protection semiconductor device 100 of this embodiment also includes a substrate 10, a well region 20, a drain region (N+ doped region 31), a source region (N+ doped region 32), a body region (P+ doped region 33), a gate layer 41, a field plate layer 42, a conductive layer 50, a first N+ doped region 72, a first P+ doped region 71, second N+ doped regions 61, 63 and 65, and second P+ doped regions 62 and 64. The positional arrangement of these regions is the same as that of the embodiment of FIG. 5, except that, in this embodiment, the conductive layer 50 covers the second N+ doped region 61 and a portion of the second P+ doped region 62 at the first end of the field plate layer 42, covers a portion of the second N+ doped region 63 at the second end of the field plate layer 2, and covers a portion of adjacent surfaces of the second N+ doped region 65 and the second P+ doped region 64. That is, the conductive layer 50 covers a portion of the second N+ doped region 65 and a portion of the second P+ doped region 64 that are adjacent to each other. This forms series-connected forward PN junctions in the field plate layer 42. Specifically, a forward PN junction is formed between the second P+ doped region 62 and the second N+ doped region 65, and a forward PN junction is also formed between the second P+ doped region 64 and the second N+ doped region 63.

In some embodiments, the required withstand voltage value may be obtained based on the operating voltage of the device to be protected, and then the direction and number of the PN junctions in the field plate layer 42 may be adjusted to obtain a suitable breakdown voltage value BV. When multiple PN junctions are formed in the field plate layer 42, the multiple PN junctions are connected in series. The ESD protection semiconductor devices of embodiments of the present disclosure change the single-layer polysilicon structure of the GGNMOS to a double-layer polysilicon structure, introduce a first N+ doped region and a first P+ doped region of high-concentration between the two sections of polysilicon, and then introduce one or more forward or reverse PN junctions in the field plate layer 42. This changes the junction breakdown between the N+ doped region and the P-type well region to the junction breakdown between the high-concentration N+ doped region and the P+ doped region, and at the same time enables to adjust the withstand voltage through the one or more PN junctions in the field plate layer 42. The value of the breakdown voltage BV needed may then be obtained by adjustment based on a combination of the two aspects. The embodiments are stable and reliable in scenarios of both low-frequency and high-frequency signals, and provide a better protection effect to internal circuit of chips.

In view of above, an embodiment semiconductor device may include a well region in a substrate, which extends from a top surface of the substrate into the substrate. A drain region and a source region are disposed in the well region, and extend from a top surface of the well region into the well region. The drain region may be located at a first end of the well region, and the source region may be located at a second end of the well region opposite to the first end of the well region. The drain region may be connected to a device to be protected for electrostatic discharge (ESD), e.g., connected to a pin of the device. The source region may be connected to a ground. The drain region may be an N+ doped region extending from the top surface of the well region into the well region. The source region may be an N+ doped region extending from the top surface of the well region into the well region.

A gate layer and a field plate layer may be disposed on the top surface of the well region between the first end and the second end of the well region. The gate layer and the field plate layer are spaced apart over the well region, with a gap provided between the gate layer and the field plate layer. The gate layer and the field plate layer may be located between the source region and the drain region, the gate layer is adjacent to the source region, and the field plate layer is adjacent to the drain region. The gate layer may be grounded.

A first N+ doped region and a first P+ doped region may be disposed in the well region between the gate layer and the field plate layer and adjacent to each other. The first N+ doped region and the first P+ doped region may extend from the top surface of the well region into the well region. The field plate layer includes a first end and a second end opposite to the first end of the field plate layer. The first end of the field plate layer may be adjacent to and electrically connected to the drain region, and the second end of the field plate layer may be electrically connected to the first N+ doped region. In some embodiments, the first N+ doped region may be adjacent to the gate layer and the first P+ doped region may be adjacent to the field plate layer. In some embodiments, the first N+ doped region may be adjacent to the field plate layer and the first P+ doped region may be adjacent to the gate layer. The first P+ doped region may partially surround the first N+ doped region.

A conductive layer may be disposed over and covering the source region, the drain region, the gate layer, a portion of the field plate layer, and a portion of the first N+ doped region. The conductive layer may expose the first P+ doped region, expose a portion of the field plate layer, and expose a portion of the first N+ doped region.

One or more N+ doped regions and one or more P+ doped regions may be alternately arranged in the field plate layer. At least one PN junction may be formed by the one or more N+ doped regions and the one or more P+ doped regions in the field plate layer. The at least one PN junction may include a forward or a reverse PN junction.

The One or more N+ doped regions and the one or more P+ doped regions may include a second N+ doped region disposed at the first end of the field plate layer, a third N+ doped region disposed at the second end of the field plate layer, and a second P+ doped region disposed between the second N+ doped region and the third second N+ doped region. In some embodiments, the conductive layer may cover the second N+ doped region, a portion of the second P+ doped region adjacent to the second N+ doped region, and a portion of the third N+ doped region away from the second P+ doped region, as shown in FIG. 2 or FIG. 5. In some embodiments, the conductive layer may cover a portion of the second N+ doped region adjacent to the drain region, the third N+ doped region, and a portion of the second P+ doped region adjacent to the third N+ doped region, as shown in FIG. 3. In some embodiments, the conductive layer may cover a portion of the second N+ doped region adjacent to the drain region, and a portion of the third N+ doped region away from the second P+ doped region, as shown in FIG. 4. In some embodiments, the one or more N+ doped regions and the one or more P+ doped regions may further include a fourth N+ doped region and a third P+ doped region that are disposed between the third N+ doped region and the second P+ doped region. The fourth N+ doped region and the third P+ doped region may be exposed by the conductive layer (as shown in FIG. 5), or partially covered by the conductive layer (as shown in FIG. 6).

In addition, embodiments of the present disclosure also provide an integrated circuit, which includes the ESD protection semiconductor devices described in the above embodiments. The integrated circuit may include any of the embodiment ESD protection semiconductor devices described above.

The ESD protection semiconductor devices and the integrated circuit of embodiments of the present disclosure are based on the GGNMOS structure, and adjacent first N+ doped region and first P+ doped region are formed in the well region, such that the breakdown junction from the N+ doped region to the P-type well region is transferred to the breakdown junction from the first N+ doped region to the first P+ doped region. Since the concentration of the first P+ doped region is high, the breakdown voltage during breakdown is low, and thus the breakdown voltage of the ESD protection semiconductor device can be reduced, and the ESD protection capability of the ESD protection semiconductor device is improved. To also ensure the voltage withstand capability of the ESD protection semiconductor device, the field plate layer separated from the gate layer is provided over the well region, and the second N+ doped region(s) and the second P+ doped region(s) are arranged in the field plate layer to form forward or reverse PN junction(s) in the field plate layer. The presence of multiple PN junctions facilitates the conduction of the NPN transistor, thereby realizing ESD protection according to need, improving the voltage withstand capability of the ESD protection semiconductor device while reducing the breakdown voltage, and improving the ESD protection capability and avoiding false triggering.

Further, the conductive layer is disposed on the field plate layer, exposing portions of the surface of the second N+ doped region(s) and the second P+ doped region(s). The second N+ doped region(s) and the second P+ doped region(s) not covered by the conductive layer form PN junction(s). This allows the direction and number of the PN junctions in the field plate layer to be adjusted by adjusting the position of the conductive layer and the number of doped regions covered by the conductive layer, thereby achieving the objective of freely adjusting the withstand voltage of the ESD protection semiconductor device. Embodiments of the present disclosure may be applied for protection of devices with various operating voltages, broadening application scenarios and enhancing applicability.

While embodiments of the present disclosure have been described above, these embodiments do not exhaustively describe all details and do not limit the application to the specific embodiments described. Obviously, many modifications and variations are possible based on the above description. These embodiments are selected and described in detail in this application in order to better explain the principles and practical applications of the present disclosure, enabling those skilled in the art to better utilize the present disclosure and to make modifications and utilize based on the resent disclosure. The present disclosure is limited only by the claims and their full scope and equivalents.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. An electrostatic discharge (ESD) protection semiconductor device, comprising:
a well region located in an upper portion of a substrate;
a drain region and a source region, located respectively at a first end and a second end opposite to each other in an upper portion of the well region, the source region being grounded, and the drain region being connected to a device pin;
a gate layer, located over the well region, adjacent to and electrically connected to the source region;
a field plate layer, located over the well region, wherein a first end of the field plate layer is adjacent to and electrically connected to the drain region, and a gap is provided between a second end of the field plate layer and the gate layer;
a first N+ doped region and a first P+ doped region, located in the well region below the gap and adjacent to each other; and
one or more second N+ doped regions and one or more second P+ doped regions, located in the field plate layer and alternately arranged;
wherein at least one forward PN junction and/or at least one reverse PN junction is/are formed in the field plate layer.

2. The ESD protection semiconductor device of claim 1, wherein the one or more second N+ doped regions comprise a second N+ doped region disposed at a first end of the field plate layer and a second N+ doped region disposed at a second end of the field plate layer, and the second N+ doped region at the first end of the field plate layer is electrically connected to the drain region, and the second N+ doped region at the second end of the field plate layer is electrically connected to the first N+ doped region in the well region.

3. The ESD protection semiconductor device of claim 2, further comprising:
a conductive layer covering a portion of the first N+ doped region and the first end and the second end of the field plate layer, wherein a PN junction is formed between the first N+ doped region not covered by the conductive layer and the first P+ doped region, and a PN junction is formed between a second N+ doped region not covered by the conductive layer and a second P+ doped region.

4. The ESD protection semiconductor device of claim 3, wherein, from the first end to the second end of the field plate layer, a forward PN junction is formed between adjacent second P+ doped region and second N+ doped region that are not covered by the conductive layer, and a reverse PN junction is formed between adjacent second N+ doped region and second P+ doped region that are not covered by the conductive layer form.

5. The ESD protection semiconductor device of claim 4, wherein when a plurality of PN junctions are formed in the field plate layer, the plurality of PN junctions are connected in series.

6. The ESD protection semiconductor device of claim 3, wherein the first P+ doped region partially surrounds the first N+ doped region, and the conductive layer exposes an entire surface of the first P+ doped region and exposes a portion of a surface of the first N+ doped region adjacent to the first P+ doped region.

7. The ESD protection semiconductor device of claim 6, wherein,
the first N+ doped region is adjacent to the gate layer, and the first P+ doped region is located between the first N+ doped region and the field plate layer, or the first N+ doped region is adjacent to the field plate layer, and the first P+ doped region is located between the first N+ doped region and the gate layer.

8. The ESD protection semiconductor device of claim 3, wherein the one or more second P+ doped regions comprise a second P+ doped region formed between the second N+ doped region at the first end of the field plate layer and the second N+ doped region at the second end of the field plate layer;
when the conductive layer completely exposes the second P+ doped region and partially exposes the second N+ doped region at the first end of the field plate layer and the second N+ doped region at the second end of the field plate layer, adjacent reverse PN junction and forward PN junction are formed in the field plate layer;
when the conductive layer exposes a portion of the second N+ doped region at the second end of the field plate layer and a portion of the second P+ doped region, a forward PN junction is formed in the field plate layer; and
when the conductive layer exposes a portion of the second N+ doped region at the first end of the field plate layer and a portion of the second P+ doped region, a reverse PN junction is formed in the field plate layer.

9. The ESD protection semiconductor device of claim 3, wherein the one or more second P+ doped regions comprise a plurality of second P+ doped regions formed between the second N+ doped region at the first end of the field plate layer and the second N+ doped region at the second end of the field plate layer; and
when the conductive layer covers a portion of the second N+ doped region at the first end of the field plate layer and a portion of the second N+ doped region at the second end of the field plate layer, reverse PN junctions and forward PN junctions are formed and alternately arranged in the field plate layer.

10. The ESD protection semiconductor device of claim 1, wherein when a plurality of PN junctions are formed in the field plate layer, the plurality of PN junctions are connected in series.

11. The ESD protection semiconductor device of claim 1, wherein, when the ESD protection semiconductor device is in operation and the drain region receives an electrostatic pulse, a PN junction in the field plate layer is turned on, and a reverse PN junction formed by the first N+ doped region and the first P+ doped region breaks down, such that a current flows from the well region to the source region, and a transistor formed by the drain region, the well region and the source region is turned on to form a current discharge path.

12. An integrated circuit comprising the ESD protection semiconductor device of claim 1.

13. A semiconductor device, comprising
a well region in a substrate, extending from a top surface of the substrate into the substrate;
a drain region and a source region in the well region, extending from a top surface of the well region into the well region, wherein the drain region is located at a first end of the well region, the source region is located at a second end of the well region opposite to the first end of the well region, and the drain region is connected to a device to be protected for electrostatic discharge (ESD);
a gate layer and a field plate layer, disposed on the top surface of the well region between the first end and the second end of the well region and spaced apart, wherein the gate layer is adjacent to the source region, and the field plate layer is adjacent to the drain region;
a first N+ doped region and a first P+ doped region, located in the well region between the gate layer and the field plate layer, and adjacent to each other;
a conductive layer covering the source region, the drain region, the gate layer, a portion of the field plate layer, and a portion of the first N+ doped region; and
one or more N+ doped regions and one or more P+ doped regions alternately arranged in the field plate layer, wherein at least one PN junction is formed by the one or more N+ doped regions and the one or more P+ doped regions in the field plate layer.

14. The semiconductor device of claim 13, wherein,
the first N+ doped region is adjacent to the gate layer and the first P+ doped region is adjacent to the field plate layer; or
the first N+ doped region is adjacent to the field plate layer and the first P+ doped region is adjacent to the gate layer.

15. The semiconductor device of claim 13, wherein,
the one or more N+ doped regions comprise a second N+ doped region disposed at a first end of the field plate layer, and a third N+ doped region disposed at a second end of the field plate layer opposite to the first end of the field plate layer, the first end of the field plate layer adjacent to the drain region; and
the one or more P+ doped regions comprise a second P+ doped region disposed between the second N+ doped region and the third second N+ doped region.

16. The semiconductor device of claim 15, wherein,
the conductive layer covers the second N+ doped region, a portion of the second P+ doped region, and a portion of the third N+ doped region; or
the conductive layer covers a portion of the second N+ doped region, a portion of the second P+ doped region, and the third N+ doped region.

17. The semiconductor device of claim 16, wherein the one or more N+ doped regions and the one or more P+ doped regions further comprise a fourth N+ doped region and a third P+ doped region that are disposed between the third N+ doped region and the second P+ doped region and that are exposed by the conductive layer.

18. The semiconductor device of claim 16, wherein the one or more N+ doped regions and the one or more P+ doped regions further comprise a fourth N+ doped region and a third P+ doped region that are disposed between the third N+ doped region and the second P+ doped region, and that are partially covered by the conductive layer.

19. The semiconductor device of claim 15, wherein the conductive layer covers a portion of the second N+ doped region and a portion of the third N+ doped region, and exposes the second P+ doped region.

20. A semiconductor device, comprising
a substrate;
a well region in the substrate, extending from a top surface of the substrate into the substrate;
a drain region and a source region in the well region, extending from a top surface of the well region into the well region, wherein the drain region is located at a first end of the well region, the source region is located at a second end of the well region opposite to the first end of the well region, the source region is grounded, and the drain region is connected to a device to be protected for electrostatic discharge (ESD);
a gate layer and a field plate layer on the top surface of the well region between the first end and the second end of the well region, wherein the gate layer and the field plate layer are spaced apart with a gap in between, the gate layer is adjacent to and electrically connected to the source region, and the field plate layer is adjacent to the drain region;
a first N+ doped region and a first P+ doped region, located in the well region below the gap, and adjacent to each other;
a conductive layer covering the source region, the drain region, the gate layer, a portion of the field plate layer, and a portion of the first N+ doped region; and
one or more N+ doped regions and one or more P+ doped regions alternately arranged in the field plate layer, wherein the one or more N+ doped regions and the one or more P+ doped regions comprise:
a second N+ doped region disposed at a first end of the field plate layer, the first end of the field plate layer adjacent to and electrically connected to the drain region;
a third N+ doped region disposed at a second end of the field plate layer opposite to the first end of the field plate layer, the second end of the field plate layer electrically connected to the first N+ doped region; and
at least one second P+ doped region disposed between the second N+ doped region and the third second N+ doped region;
wherein at least one PN junction is formed by the one or more N+ doped regions and the one or more P+ doped regions in the field plate layer, the at least one PN junction including a forward PN junction or a reverse PN junction.
